(19) United States
(12) Patent Application Publication
(10) Pub. No.: US 2008/0315355 A1
(43) Pub. Date: Dec. 25, 2008

(54) SEMICONDUCTOR DEVICE AND METHOD OF MANUFACTURING THE SAME

(75) Inventor: Kouki Oda, Kumamoto-shi (JP)

Correspondence Address: YOUNG & THOMPSON, 209 Madison Street, Suite 500, ALEXANDRIA, VA, 22314, US

(73) Assignee: NEC ELECTRONICS CORPORATION, KAWASAKI (JP)

(21) Appl. No.: 12/144,029

(22) Filed: Jun. 23, 2008

(30) Foreign Application Priority Data
Jun. 21, 2007 (JP) 2007/163995

(51) Int. Cl. H01L 23/525; H01L 21/44

(52) U.S. Cl. 257/529; 438/586; 257/E23.149; 257/E21.476

(57) ABSTRACT

A semiconductor device in accordance with the present invention includes a fuse formed on a substrate; a first insulator film provided so as to cover the fuse; cavity-forming pattern provided in the layer on the first insulator film; and second insulator film provided so as to cover the cavity-forming pattern, wherein the cavity-forming pattern is patterned so that a spatial area is produced therebetween and the second insulator film covers the cavity-forming pattern so that a cavity is produced in the spatial area.

### BACKGROUND OF THE INVENTION

The present invention relates to a semiconductor device having fuses and a method of manufacturing the semiconductor device.

In some cases, a semiconductor device is provided with fuses and redundant circuits (redundancy) in order to substitute a defective circuit or circuits. If some circuits become defective, these circuits are replaced with redundant circuits by blowing fuses. Thus, a defective chip is saved.

Methods of blowing a fuse include irradiating laser light at the fuse and flowing an overcurrent through the fuse. When blowing the fuse by irradiating laser light, it is desired that only the portion of the fuse to be cut off is blown and no damage is inflicted upon portions not to be cut off. Japanese Patent Laid-Open Nos. 2004-153174 and 11-345880 describe techniques intended to reliably blow only the portion of a fuse to be cut off.

On the other hand, when blowing a fuse, it is required to reliably cut off the fuse. FIG. 1 is an example drawing illustrating a cross-sectional structure of a fuse part. In the example shown in this drawing, a fuse is formed on an interlayer film 101. The fuse is covered with an interlayer film 102. Although not shown in the figure, there are provided interconnects in locations other than a fuse-forming region. The interconnects are provided in a plurality of layers through interlayer films. Consequently, a region wherein a fuse is formed also has a laminated structure composed of a plurality of interlayer films. In the example of FIG. 1, an interlayer film 103 is provided on the interlayer film 102.

In the case of such a structure wherein a plurality of interlayer films are provided on a fuse as shown in FIG. 1, the total thickness of films covering the fuse increases. If the thickness of films on and above the fuse increases, energy to be used when blowing the fuse is suppressed by the interlayer films and the like on and above the fuse, thereby possibly resulting in incomplete fuse blowout. Accordingly, there is a desire for a technique capable of preventing a failure in fuse blowout.

Examples of techniques to prevent a fuse blowout failure include those described in Japanese Patent Laid-Open Nos. 10-107146 and 2006-73698.

Japanese Patent Laid-Open No. 10-107146 describes a technique to provide a fuse metal pattern and a dummy fuse metal pattern in vicinity to each other on a substrate. According to Japanese Patent Laid-Open No. 10-107146, the fuse metal pattern and the dummy fuse metal pattern are provided in vicinity to each other and, therefore, a void is produced when covering these patterns with a CVD insulator film. Since the void is formed in the CVD insulator film, a force to cause a fuse metal to fly apart is increased when blowing the fuse metal.

In addition, Japanese Patent Laid-Open No. 2006-73698 describes a technique to provide a dummy opening for each of a plurality of interlayer insulator films on and above a fuse. A dummy opening provided in each interlayer insulator film is filled with an interlayer insulator film one layer above the interlayer insulator film wherein the dummy opening is provided, and a dummy opening provided in the uppermost interlayer insulator film is filled with a passivation film. The patent document states that such a configuration as described above causes interlayer insulator films on and above the fuse to be easily destroyed and enables the prevention of a fuse blowout failure.

However, the inventor of the present application has become aware that the techniques described above have the problems described below. That is, the structures described in Japanese Patent Laid-Open Nos. 10-107146 and 2006-73698 mean that voids and openings are provided in the interlayer film directly covering the fuse. In such structures as described above, it is presumed that the strength of the interlayer film directly covering the fuse has decreased. If the strength of the interlayer film directly covering the fuse is insufficient, an impurity may diffuse into the fuse and alter the physical properties thereof, thereby causing the fuse to have a higher resistance. Alternatively, the stress distribution of the fuse may become non-uniform, possibly resulting in stress migration. Since whether or not to blow fuses is determined based on the result of an operation test, there can be an unblown fuse or fuses. For the unblown fuses, an alteration in the physical properties thereof or stress migration becomes an issue.

### SUMMARY

A semiconductor device in accordance with the present invention includes a fuse formed on a substrate; a first insulator film provided so as to cover the fuse; a cavity-forming pattern provided above the first insulator film; and second insulator film provided so as to cover the cavity-forming pattern. The cavity-forming pattern is patterned to form a spatial area therebetween. The second insulator film covers the cavity-forming pattern to form a cavity in the spatial area.

If the semiconductor device is configured as described above, no such treatments as to decrease the film strength are applied to the first insulator film covering the fuse. Consequently, the fuse is fully protected by the first insulator film even when the fuse is not blown. In addition, the cavities are formed in each of the second insulator films provided on and above the first insulator film. In the presence of the cavity, the second insulator film becomes easy to be destroyed. Consequently, it is possible to reliably blow the fuse.

According to the present invention, there are provided a semiconductor device wherein fuses to be cut off can be reliably blown while fully protecting fuses not to be blown, and a method of manufacturing the semiconductor device.

### BRIEF DESCRIPTION OF THE DRAWINGS

The above and other objects, advantages and features of the present invention will be more apparent from the following description taken in conjunction with the accompanying drawings, in which:

FIG. 1 is a schematic cross-sectional view used to explain the structure of a fuse part;

FIG. 2 is a schematic cross-sectional view used to explain the structure of a semiconductor device of a first embodiment;

FIG. 3A is an explanatory drawing used to explain a relative positional relationship between a cavity-forming pattern and a fuse;

FIG. 3B is another explanatory drawing used to explain a relative positional relationship between a cavity-forming pattern and a fuse;

FIG. 4 is a flowchart showing a method of manufacturing a semiconductor device of a first embodiment;

FIG. 5A is a cross-sectional process drawing illustrating a method of manufacturing a semiconductor device of a first embodiment;

FIG. 5B is cross-sectional process drawing illustrating a method of manufacturing a semiconductor device of a first embodiment;

FIG. 5C is cross-sectional process drawing illustrating a method of manufacturing a semiconductor device of a first embodiment;

FIG. 5D is cross-sectional process drawing illustrating a method of manufacturing a semiconductor device of a first embodiment;

FIG. 6 is a schematic cross-sectional view illustrating a semiconductor device of a second embodiment; and

FIG. 7 is a schematic cross-sectional view illustrating a semiconductor device of a third embodiment.

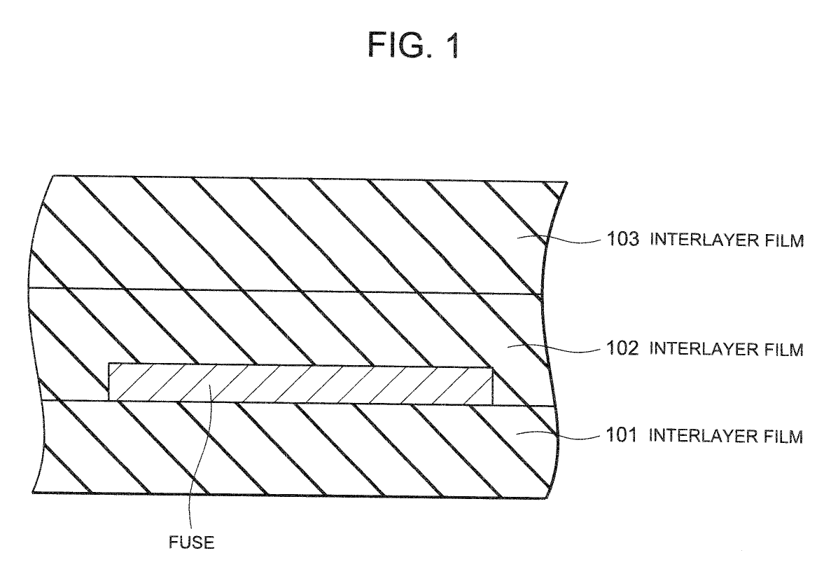

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

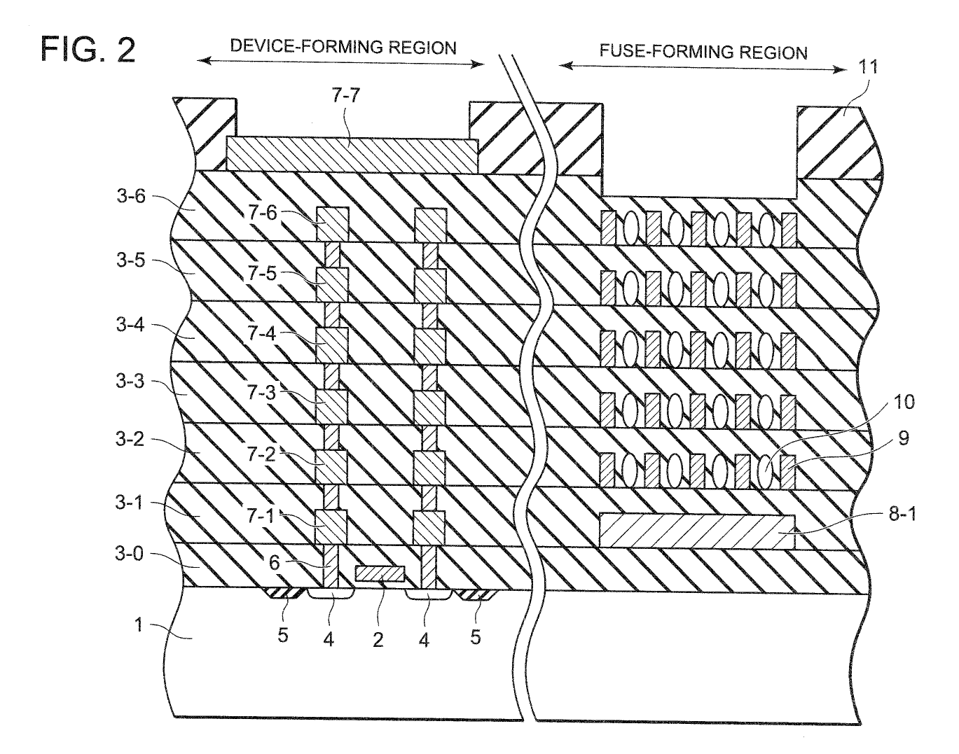

Hereinafter, embodiments of the present invention will be described while referring to the accompanying drawings. FIG. 2 is a schematic cross-sectional view illustrating a configuration before a fuse is blown in a semiconductor device of the present embodiment. The semiconductor device includes a substrate 1 (for example, silicon substrate), a plurality of insulator films 3-0 to 3-6 (for example, silicon dioxide films) formed on the substrate 1, and a passivation film 11 (for example, silicon nitride film) covering the uppermost interlayer insulator film 3-6. In addition, the semiconductor device is provided with a device-forming region wherein a semiconductor transistor and the like are formed and a fuse-forming region wherein a fuse is formed.

In the device-forming region, isolation regions 5 and source/drain regions 4 are formed on a surface of the substrate 1. Also on the surface of the substrate 1, there is formed the first insulator film 3-0. A gate electrode 2 is formed in the insulator film 3-0. The gate electrode 2 is electrically insulated from the surface of the substrate 1. A semiconductor transistor is formed by the gate electrode 2 and the source/drain regions 4. The isolation regions 5 are insulating regions which isolate from each other regions wherein semiconductor transistors are formed.

Interconnect layers 7 (7-1 to 7-7) are provided on the respective insulator films 3 (3-0 to 3-6) in the device-forming region. Conductive plugs 6 are buried in the respective insulator films 3. The upper- and lower-layer interconnects 7 are connected to each other by the plugs 6. A part of the interconnect 7-7 provided on the uppermost insulator film 3-6 serves as a pad part. In the pad part, the passivation film 11 has an opening. The interconnects 7 are formed of aluminum. The interconnect 7-1 is connected to the source/drain regions 4 through plugs.

Next, the structure of the fuse-forming region will be described. In the fuse-forming region, there are provided a fuse 8-1, cavity-forming pattern 9 and cavitiy 10.

The fuse 8-1 is provided on the insulator film 3-0 and is covered with the insulator film 3-1 (first insulator film). This means that the fuse 8-1 is provided in the same layer as the interconnect layer 7-1. In addition, the fuse 8-1 is formed of the same material as the interconnect 7-1. That is, the fuse 8-1 is formed of aluminum in the present embodiment. As will be described later, the fuse 8-1 is formed in the same step as the interconnect layer 7-1.

The cavity-forming pattern 9 is provided on each of the insulator films 3-1 to 3-5 and is covered with each of the insulator films 3-2 to 3-6 (second insulator films). This means that the cavity-forming pattern 9 is provided in the same layer as each of the interconnect layers 7-2 to 7-6. In addition, the cavity-forming pattern 9 is formed of the same material as the interconnects 7-2 to 7-6. That is, the cavity-forming pattern 9 is formed of aluminum in the present embodiment. As will be described later, the cavity-forming pattern 9 is formed in the same step as the interconnects 7-2 to 7-6.

The cavity-forming pattern 9 is intended to cause the cavitiy 10 to be produced at the time of manufacturing and is patterned at narrow pitch so that spatial area is produced. If the cavity-forming pattern 9 is patterned at narrow pitch, the spatial area is not filled with the insulator film 3 when depositing the insulator film 3, thereby causing the cavity 10 to be produced. Specifically, it is preferable that each cavity-forming pattern 9 be patterned so that the aspect ratio thereof is 3 or greater, since the cavity 10 becomes easy to be produced. The aspect ratio is represented by a ratio of the height of each cavity-forming pattern 9 to the spacing width thereof (height÷spacing width). The spatial area become more difficult to be filled with the insulator film 3 when depositing the insulator film 3 and the cavity 10 becomes easier to be produced, with the increase of the aspect ratio. More specifically, it is preferable that each spatial area to be 0.20 to 0.15 μm or smaller if the thickness of each cavity-forming pattern 9 is 0.6 to 0.7 μm.

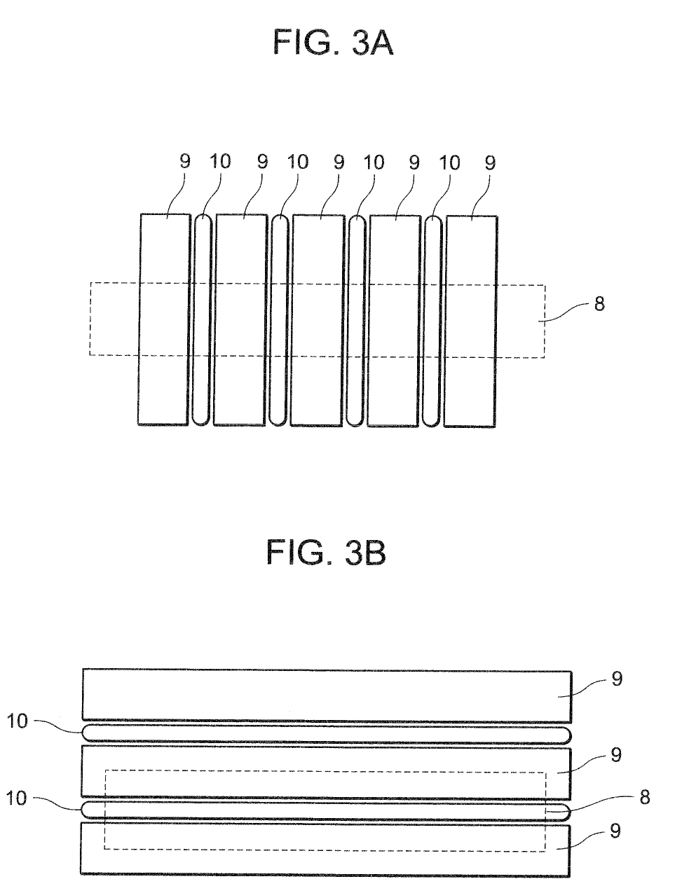

FIG. 3A is a plan view illustrating a relative positional relationship between the fuse 8 and cavity-forming pattern 9 when a semiconductor device is viewed from above. In practice, the fuse and the cavity-forming pattern 9 is covered with the insulator film 3 and is therefore invisible. However, the fuse and the cavity-forming pattern 9 is shown in a perspective manner for purposes of illustration As illustrated in FIG. 3A, the cavity-forming pattern 9 is patterned so as to be orthogonal to the fuse 8 on a surface of the substrate. Consequently, cavity 10 is formed so as to be also orthogonal to the fuse 8 on the substrate surface. As the result of the cavity 10 being formed in a position appropriate for the fuse 8, it is possible to decrease the strength of a film above the fuse 8 and, thereby, reliably blow the fuse 8.

Note that the cavity-forming pattern 9 needs not necessarily to be provided so as to be orthogonal to the fuse 8. The cavity-forming pattern 9 may be patterned in parallel with the fuse 8, as shown in FIG. 3B for example, as long as the cavity-forming pattern 9 is disposed so that cavity is formed above the fuse 8.

Referring again to FIG. 2, an opening is provided in the passivation film 11 in the fuse-forming region. This is for the purpose of making it easy for films on and above the fuse to be destroyed.

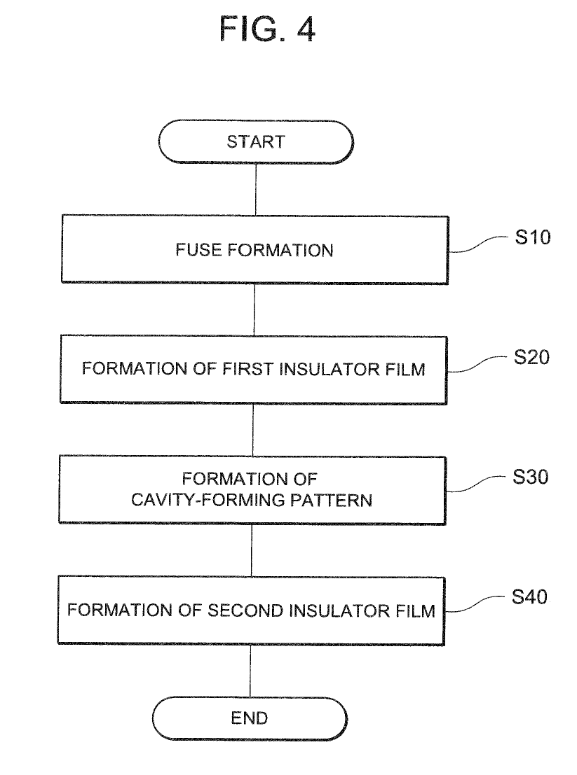

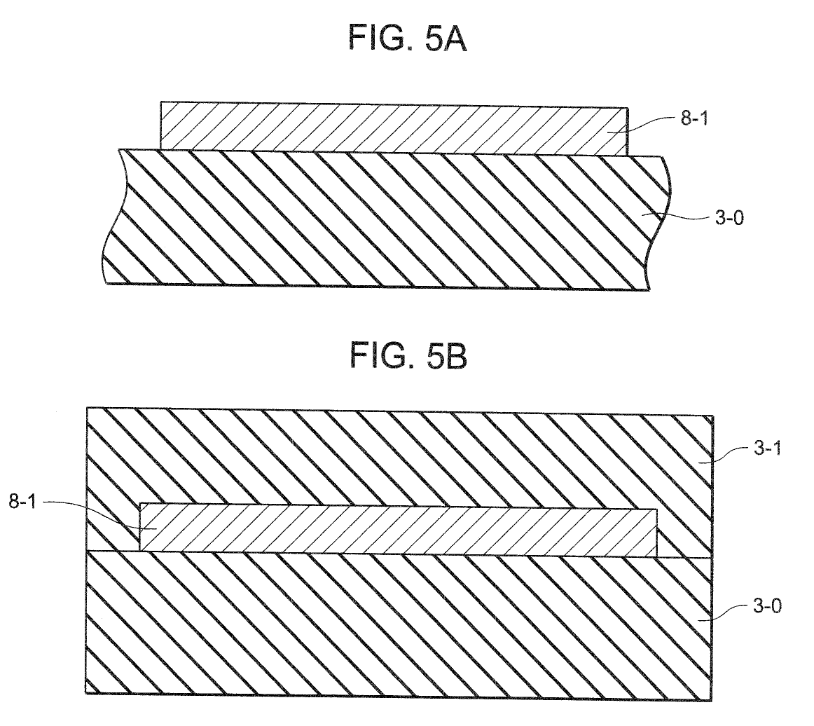

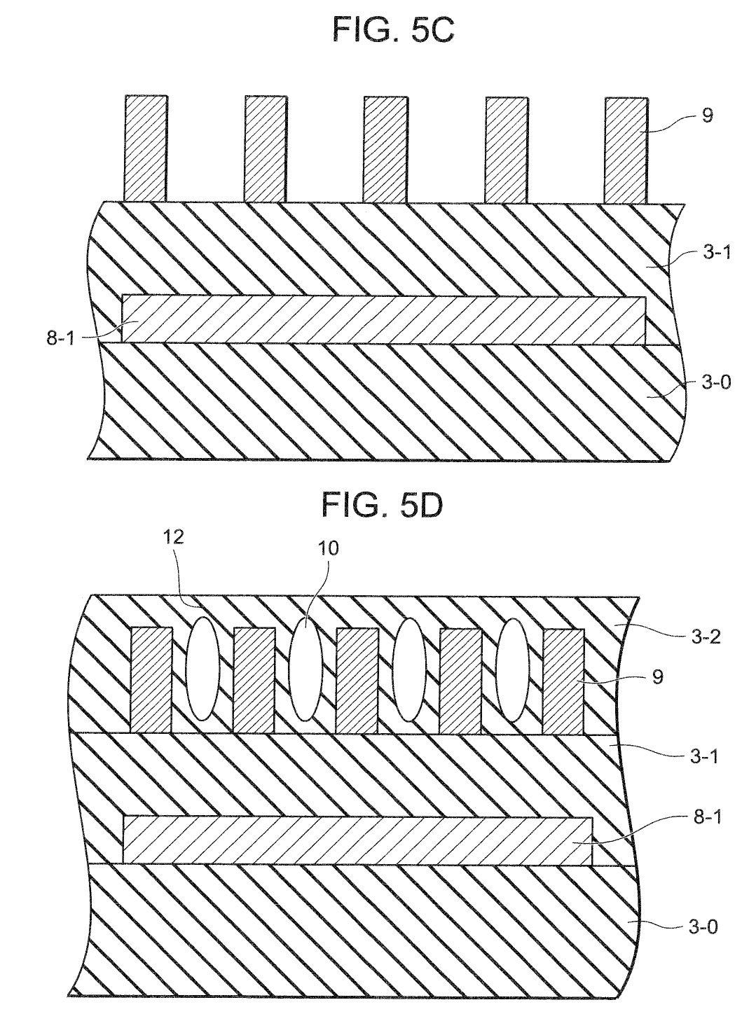

Subsequently, an explanation will be made of a method of manufacturing a semiconductor device having such a configuration as described above. FIG. 4 is a flowchart showing a method of manufacturing the semiconductor device of the present embodiment. FIGS. 5A to 5D are cross-sectional process drawings in the fuse-forming region.

### Step S10: Fuse Formation

First, the fuse 8-1 is formed on the insulator film 3-0 as shown in FIG. 5A. Note that a semiconductor transistor and the insulator film 3-0 are formed on the substrate 1 before the fuse 8 is formed. However, these steps do not directly relate to the subject matter of the present embodiment and, therefore, will not be explained here. Since the fuse 8-1 is made of the same material as the interconnect 7-1 (aluminum in the present embodiment), the fuse 8-1 can be formed in the same step as the interconnect 7-1 in the device-forming region (see FIG. 2).

### Step S20: Formation of First Insulator Film

Next, as shown in FIG. 5B, the insulator film 3-1 (first insulator film) is formed so as to cover the fuse 8-1. The insulator film 3-1 is formed using, for example, a CVD process. After forming the insulator film 3-1, the surface thereof is planarized by means of chemical mechanical polishing (CMP).

### Step S30: Formation of Cavity-Forming Pattern

Next, the cavity-forming pattern 9 is formed on the insulator film 3-1 as shown in FIG. 5C. The cavity-forming pattern 9 is formed in the same step as the interconnect 7-2 in the device-forming region. As described already, the cavity-forming pattern 9 is patterned and formed at narrow pitch.

### Step S40: Formation of Second Insulator Film

Next, the cavity-forming pattern 9 is covered by depositing the insulator film 3-2 (second insulator film) as shown in FIG. 5D. The insulator film 3-2 is formed using, for example, a CVD process. At this time, cavity 10 is produced since a spatial area between cavity-forming pattern 9 is sufficiently narrow and, therefore, the insulator film 3-2 is not fully filled therein. Note that the insulator film 3-2 is continuous in the upper portion thereof. After film-forming the insulator film 3-2, the surface thereof is planarized using a CMP method.

If the cavity-forming pattern 9 is deposited on the condition that the amount of deposition in the upper portion thereof is larger than the amount of deposition on the side wall thereof when depositing the insulator film 3-2 using a CVD process, the cavity 10 becomes easier to be formed. Under such a condition as described above, the insulator film 3-2 is deposited so as to swell up from the upper portion of each cavity-forming pattern 9, thus becoming easy to connect with a part of the insulator film 3-2 deposited from the upper portion of an adjacent cavity-forming pattern 9 on the obliquely upper side thereof. On the other hand, since the amount of deposition toward the side wall of each cavity-forming pattern 9 is relatively small, part of the insulator film 3-2 become difficult to connect with each other in a spatial area and, therefore, each cavity 10 is easily formed. In a normal semiconductor manufacturing method, cavity is prevented from being produced. In the present embodiment, however, the insulator film 3-2 is deposited under such a condition as to form cavity in a positive manner.

If the insulator film 3-2 is deposited at a lower level of bias power when depositing the insulator film 3-2 using a high-density plasma (HDP) apparatus, cavity becomes easier to be formed. In a case where the HDP apparatus is used, the deposition and etching of the insulator film 3-2 are performed at the same time. If the insulator film 3-2 is deposited under a condition wherein bias power is lowered, then etching becomes difficult to be performed. Therefore, parts of the insulator film 3-2 become easy to connect with each other on the obliquely upper side of each cavity-forming pattern 9 and each cavity 10 becomes easy to be formed in the bottom of a spatial area.

The insulator film 3-2 in this step is formed in the same step as the step of forming the insulator film 3-2 in the device-forming region. In order to prevent the cavity 10 from being produced in the device-forming region at this time, it is only necessary to pattern the interconnect 7-2 at such narrow pitches as not to allow the cavity 10 to be produced Specifically, the cavity 10 become difficult to be produced if each cavity-forming pattern 9 is patterned so that the aspect ratio thereof is 3 or less. Note that cavity may also be formed in the device-forming region as long as they have no such an influence as to cause migration in the interconnects 7.

After forming the insulator film 3-2, the processes of steps S30 and 40 are repeated to form the insulator films 3-3 to 3-6. The cavity-forming pattern 9 and the cavity 10 are formed in each insulating layer 3. In addition, the passivation film 11 is formed on the uppermost insulator film 3-6 and openings are created in regions corresponding to pad parts and the fuse 8-1. Consequently, there is fabricated a semiconductor device having the structure shown in FIG. 2.

An operation test is performed on the semiconductor device fabricated as described above. Then, a determination is made, based on the result of the operation test, as to whether to blow the fuse 8-1 or leave it over as is. The fuse 8-1 can be blown by, for example, flowing an overcurrent through the fuse or irradiating laser light onto the fuse. Since the cavity 10 is formed in the respective layers (3-2 to 3-6) of an insulator film 3 on and above the fuse 8-1 at that time and, therefore, the insulator films are sparse, energy used to blow the fuse 8-1 is prevented from being suppressed by the respective insulator films (3-2 to 3-6). Specifically, layers of the insulator film 3 above the cavity 10 is now thin as the result of the cavity 10 having been formed. The impact of fuse blowout is absorbed by these thinned parts and the thinned parts are easily destroyed Since layers of the insulator film 3 on and above the fuse 8-1 are now easy to be destroyed, it is possible to reliably blow the fuse 8-1.

The insulator film 3-1 directly covering the fuse 8-1 is not processed in particular. Accordingly, there are prevented stress migration due to a non-uniform stress distribution and an alteration in the physical properties of the fuse due to the ingress of an impurity or impurities in a case wherein the fuse 8-1 is not blown.

In the present embodiment, an explanation has been made of a case wherein the cavity 10 is formed in each of the insulator films 3-2 to 3-6. However, the cavity 10 may not necessarily be formed in all of the insulator films 3-2 to 3-6. The effect of facilitating fuse blowout is available if the cavity 10 is formed in at least one layer.

### Second Embodiment

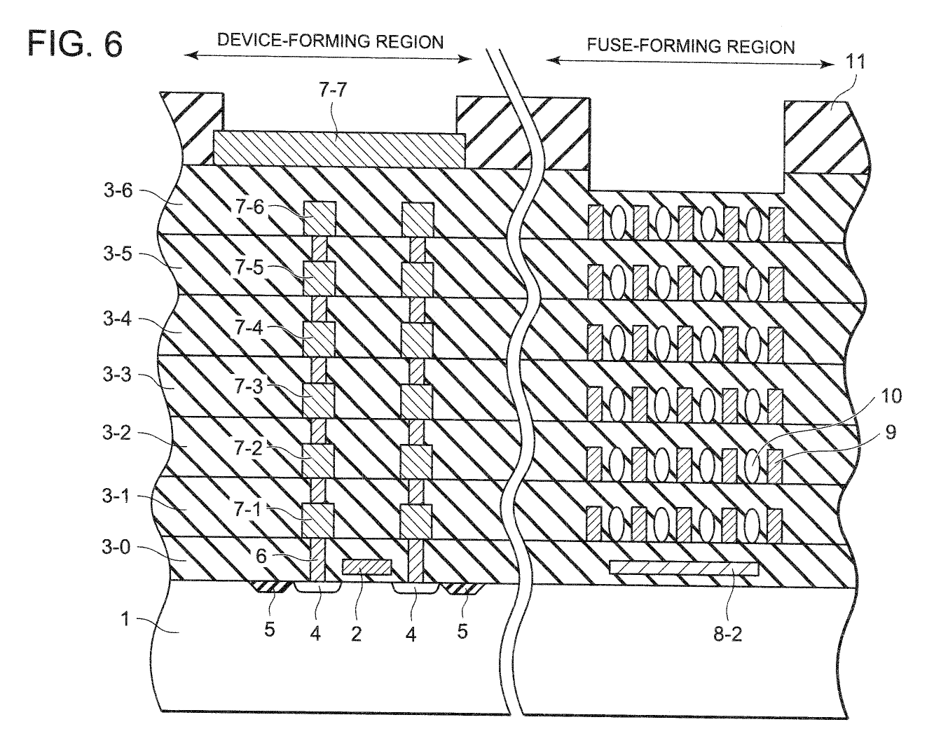

Next, an explanation will be made of a second embodiment. FIG. 6 is a schematic cross-sectional view illustrating the structure of a semiconductor device of the present embodiment. In the first embodiment, an explanation has been made of a case wherein the fuse 8-1 is formed of the same material and in the same step as the interconnect 7-1 in the device-forming region. In the present embodiment, however, a fuse 8-2 is formed in the same step as the gate electrode 2 of a semiconductor transistor. The rest of the structure is the same as that in the first embodiment and, therefore, will be explained in no more detail.

As shown in FIG. 6, the gate electrode 2 is formed in an insulator film 3-0 in a device-forming region. The gate electrode 2 is formed of polysilicon. In addition, the fuse 8-2 is buried in the insulator film 3-0 (first insulator film) in a fuse-forming region. The fuse 8-2 is formed of polysilicon as with the gate electrode 2. The gate electrode 2 and the fuse 8-2 are formed in the same step.

In the present embodiment, cavity-forming pattern 9 and cavity 10 are provided on insulator films 3-0 to 3-5 in the fuse-forming region. That is, the cavity 10 is provided in insulator films 3-1 to 3-6 (second insulator films). Neither cavity-forming pattern 9 nor cavity 10 is buried in the insulator film 3-1 (first insulator film).

Also in a case wherein a polysilicon fuse is used rather than a fuse made of metal such as aluminum, as in the present embodiment, it is possible to provide the same effect as that of the first embodiment by providing cavity 10 in layers upper than the layer wherein the fuse 8-1 is buried. That is, fuse blowout is reliably achieved when blowing the fuse 8-2 and the fuse can be prevented from being affected by stress migration or altered in terms of the physical properties thereof when not blowing the fuse 8-2.

### Third Embodiment

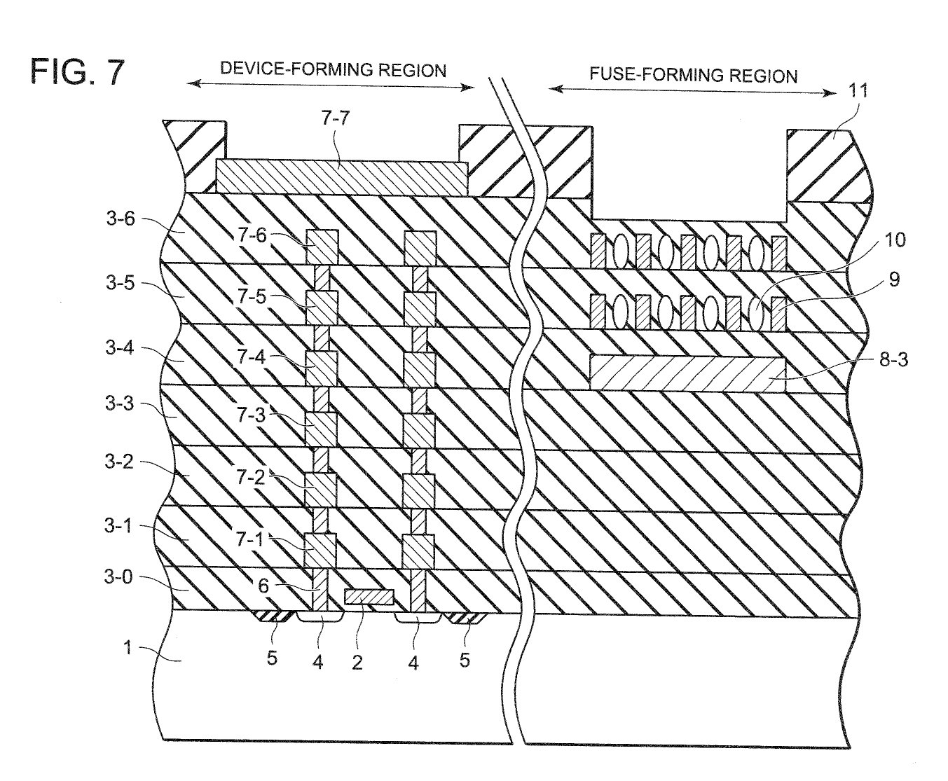

Subsequently, an explanation will be made of a third embodiment. FIG. 7 is a schematic cross-sectional view illustrating the structure of a semiconductor device of the present embodiment. In the first embodiment, an explanation has been made of a case wherein the fuse 8-1 is formed of the same material and in the same step as the interconnect 7-1 in the device-forming region. In the present embodiment, however, a fuse 8-3 is formed of the same material and in the same step as an interconnect 7-4 in a device-forming region. That is, the fuse 8-3 is provided in an insulator film 3-4 (on an insulator film 3-3).

In the present embodiment, cavity-forming pattern 9 and cavity 10 are provided on insulator films 3-4 and 3-5. That is, the cavity 10 is provided in insulator films 3-5 and 3-6 (second insulator films). Neither cavity-forming pattern 9 nor cavity 10 is formed in layers lower than the insulator film 3-4 (first insulator film).

The rest of the structure is the same as that in the first embodiment and, therefore, will be explained in no more detail.

As described in the present embodiment, the position of a layer wherein a fuse is provided is not limited in particular. That is, even in a case wherein a fuse is provided in any of intermediate layers (3-1 to 3-5), among a plurality of layers formed of insulator films 3-0 to 3-6, it is possible to provide the same effect as those of the earlier-described embodiments as the result of cavity 10 being formed in layers upper than that intermediate layer. That is, fuse blowout is reliably achieved when blowing the fuse 8-3 and the fuse can be prevented from being affected by stress migration or altered in terms of the physical properties thereof when not blowing the fuse 8-3.

What is claimed is:

1. A semiconductor device comprising:
a fuse on a substrate;
a first insulator film covering said fuse;
a cavity-forming pattern on said first insulator film; and
a second insulator film covering said cavity-forming pattern so that said cavity-forming pattern has a cavity therebetween.

2. The semiconductor device according to claim 1, further comprising:
a semiconductor transistor; and
a plurality of interconnect layers above said semiconductor transistor;
wherein said fuse is provided in the same layer as at least one layer among said plurality of interconnect layers and said cavity-forming pattern is provided in the same layer as at least another layer among said plurality of interconnect layers.

3. The semiconductor device according to claim 2, wherein said interconnect, said fuse and said cavity-forming pattern is formed of aluminum.

4. The semiconductor device according to claim 1, further comprising a semiconductor transistor having a gate electrode, wherein said fuse is made of the same material and is provided in the same layer as said gate electrode.

5. The semiconductor device according to claim 4, wherein said gate electrode and said fuse are formed of polysilicon.

6. The semiconductor device according to claim 1, wherein said cavity-forming pattern has an aspect ratio of 3 or greater.

7. The semiconductor device according to claim 1, wherein said device includes a device-forming region having said transistor and a fuse-forming region having said cavity-forming pattern.

8. The semiconductor device according to claim 1, wherein said cavity forming pattern is provided in two or more interconnect layers.

9. A method of manufacturing a semiconductor device, comprising:
forming a fuse on a substrate;
forming a first insulator film so as to cover said fuse;
forming a cavity-forming pattern on said first insulator film; and
forming a second insulator film so as to cover said cavity-forming pattern;
wherein in the step of said forming a cavity-forming pattern, said cavity-forming pattern is patterned to form spatial area and, in the step of said forming said second insulator film, said cavity-forming pattern is covered with said second insulator film to form a cavity in said spatial area.

10. The method of manufacturing a semiconductor device according to claim 9, further comprising:
forming a semiconductor transistor; and
forming a plurality of interconnect layers above said semiconductor transistor;
wherein the step of said forming said fuse is carried out in the same step as a step of forming at least one layer of said plurality of interconnect layers, and the step of said forming cavity-forming pattern formation is carried out in the same step as a step of forming at least another layer of said plurality of interconnect layers.

11. The method of manufacturing a semiconductor device according to claim 9, further comprising:
forming a semiconductor transistor including the step of forming a gate electrode;
wherein the step of said forming said gate electrode is carried out in the same step as the step of forming said fuse.

12. The method of manufacturing a semiconductor device according to claim 9, wherein said cavity-forming pattern is patterned so that the aspect ratio thereof is 3 or greater.

13. The method of manufacturing a semiconductor device according to claim 9, wherein said second insulator film is deposited on a condition that a thickness of deposition in an upper portion of said cavity-forming pattern is greater than a thickness of deposition on a side wall of said cavity-forming pattern.

14. The method of manufacturing a semiconductor device according to claim 9, further comprising:
blowing said fuse after the step of said forming a second insulator film.

15. The method of manufacturing a semiconductor device according to claim 9, wherein said device includes a device-forming region having said transistor and a fuse-forming region having said cavity-forming pattern.

16. The method of manufactureing a semiconductor device according to claim 9,
wherein said cavity-forming pattern is provided in two or more interconnect layers.
